(19) United States
(12) Patent Application Publication
(10) Pub. No.: US 2007/0067698 A1
(43) Pub. Date: Mar. 22, 2007

(54) Techniques to perform prefetching of content in connection with integrity validation value determination

(76) Inventors: Steven R. King, Portland, OR (US); Frank L. Berry, North Plains, OR (US)

Correspondence Address: INTEL CORPORATION;c/o INTELLEVATE, LLC, P.O. BOX 52050, MINNEAPOLIS, MN, 55402, US

(21) Appl. No.: 11/230,720

(22) Filed: Sep. 19, 2005

(51) Int. Cl. G11C 29/00

(52) U.S. Cl. 714/763

(57) ABSTRACT

Techniques are described herein that are capable to perform a retrieval of content from a destination buffer prior to completion of determining an integrity validation value on content of a source buffer. In some cases, if an integrity checking operation on content of the source buffer is successful, the content of the source buffer is copied to the destination buffer. The retrieved content may be written into a cache accessible to one or more processors.

### FIELD

The subject matter disclosed herein relates to techniques to pre-fetch content in connection with determining an integrity validation value of information.

### RELATED ART

Data communications systems typically utilize techniques to verify the integrity of received information. For example, to verify integrity of received packets, various protocols such as Remote Direct Memory Access (RDMA), Internet Small Computer System Interface (iSCSI), and Stream Control Transmission Protocol (SCTP) may use a calculation of cyclical redundancy checking (CRC) values over received packets as well as a comparison of calculated CRC values with CRC values provided with the packets. For example, RDMA is described for example at www.rdmaconsortium.com as well as in An RDMA Protocol Specification, Version 1.0 (October 2002). iSCSI is described for example at RFC 3720: Internet Small Computer Systems Interface (iSCSI) (April 2004). SCTP is described for example at The Internet Society RFC-3286, An Introduction to the Stream Control Transmission Protocol (SCTP) (May 2002). In some scenarios, it is desirable to perform a copy operation following verification of the integrity of the received packet. For example, an integrity validation operation may be followed by a transfer of that information to another buffer.

### BRIEF DESCRIPTION OF THE DRAWINGS

Embodiments of the present invention are illustrated by way of example, and not by way of limitation, in the figures of the accompanying drawings and in which like reference numerals refer to similar elements and in which:

FIG. 1 depicts an example computer system capable to use embodiments of the present invention;

FIG. 2 depicts an example operation of some embodiments of the present invention; and

FIG. 3 depicts an example process that can be used in some embodiments of the present invention to determine when to prefetch portions of a destination buffer.

Note that use of the same reference numbers in different figures indicates the same or like elements.

### DETAILED DESCRIPTION

Reference throughout this specification to “one embodiment” or “an embodiment” means that a particular feature, structure, or characteristic described in connection with the embodiment is included in at least one embodiment of the present invention. Thus, the appearances of the phrase “in one embodiment” or “an embodiment” in various places throughout this specification are not necessarily all referring to the same embodiment. Furthermore, the particular features, structures, or characteristics may be combined in one or more embodiments.

In some embodiments, in order to transfer content from a source buffer to a destination buffer, the content may be transferred to a cache and a destination portion of the destination buffer that the content is to overwrite may be transferred into the cache. To complete transfer of the content to the destination buffer, the content in the cache may overwrite the portion of the destination buffer in the cache and the overwritten portion may overwrite the destination portion of the destination buffer. However, in some implementations, the overwritten contents of the destination buffer in the cache are not written back into the destination buffer. For example, if another processor requests the overwritten contents of the destination buffer in the cache, such contents may be transferred to another cache or otherwise be made available. As used herein, a cache may include any type of memory device.

For example, the transfer of a portion of the destination buffer to the cache may be part of a cache coherency protocol that can be used during administration of ownership of the destination buffer by multiple central processing units. One example cache coherency protocol includes Modified-Exclusive-Shared-Invalid (MESI).

Some implementations of emerging network technologies such as RDMA may use a CRC to validate received data. In some implementations of emerging network technologies such as RDMA, only after computing and checking the CRC does the processor copy the received data to its final destination. This strict serialization of CRC followed by copy may introduce a delay between when data is received and when validated data is available for other access or use.

Some embodiments of the present invention provide for prefetching at least a portion of content from a destination buffer prior to completion of determining an integrity validation value over a portion of stored content in a source buffer. In some embodiments, the stored content in the source buffer may subsequently overwrite the portion of the destination buffer from which content was prefetched. In some embodiments, the stored content may include at least a portion of a network protocol unit received from a transmitter. As used herein, a “network protocol unit” may include any packet or frame or other format of information with a header and payload portions formed in accordance with any protocol specification.

In some embodiments, the portion of the network protocol unit that is stored content in the source buffer may be prepared for transmission through a network to a receiver and an integrity validation value determined during the integrity validation determination operation may be included in the network protocol unit transmitted to a receiver. In some embodiments, the integrity validation value may include a CRC value.

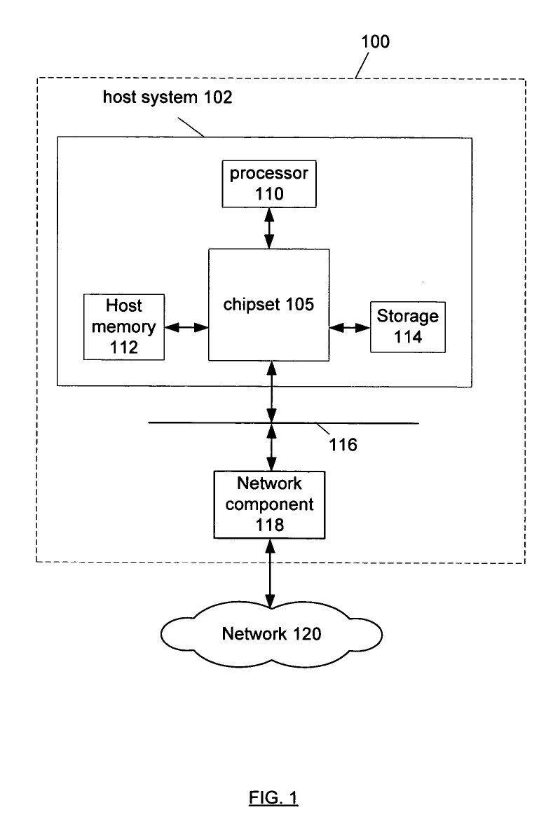

FIG. 1 depicts in block diagram form a computer system 100. Computer system 100 is a suitable system in which some embodiments of the present invention may be used. Computer system 100 may include host system 102, bus 116, and network component 118.

Host system 102 may include chipset 105, processor 110, host memory 112, and storage 114. Chipset 105 may provide intercommunication among processor 110, host memory 112, storage 114, bus 116, as well as a graphics adapter that can be used for transmission of graphics and information for display on a display device (both not depicted). For example, chipset 105 may include a storage adapter (not depicted) capable of providing intercommunication with storage 114. For example, the storage adapter may be capable of communicating with storage 114 in conformance with any of the following protocols: Small Computer Systems Interface (SCSI), Fibre Channel (FC), and/or Serial Advanced Technology Attachment (S-ATA), although other protocols may be used.

In some embodiments, chipset 105 may include data mover logic to perform transfers of information within host memory, from host memory to host system, within host system, or from host system to host memory. As used herein, a “data mover” refers to a module for moving data from a source to a destination without using the core processing module of a host processor, such as processor 110, or otherwise does not use cycles of a processor to perform data copy or move operations. By using the data mover for transfer of data, the processor may be freed from the overhead of performing data movements, which may result in the host processor running at much slower memory speeds compared to the core processing module speeds. A data mover may include, for example, a direct memory access (DMA) engine as described herein. In some embodiments, data mover could be implemented as part of processor 110, although other components of computer system 100 may include the data mover.

Processor 110 may be implemented as Complex Instruction Set Computer (CISC) or Reduced Instruction Set Computer (RISC) processors, multi-core, or any other microprocessor or central processing unit. Host memory 112 may be implemented as a volatile memory device such as but not limited to a Random Access Memory (RAM), Dynamic Random Access Memory (DRAM), or Static RAM (SRAM). Storage 114 may be implemented as a non-volatile storage device such as but not limited to a magnetic disk drive, optical disk drive, tape drive, an internal storage device, an attached storage device, flash memory, battery backed-up SDRAM (synchronous DRAM), and/or a network accessible storage device.

Bus 116 may provide intercommunication among at least host system 102 and network component 118 as well as other peripheral devices (not depicted). Bus 116 may support serial or parallel communications. Bus 116 may support node-to-node or node-to-multi-node communications. Bus 116 may be compatible with Peripheral Component Interconnect (PCI) described for example at Peripheral Component Interconnect (PCI) Local Bus Specification, Revision 2.2, Dec. 18, 1998 available from the PCI Special Interest Group, Portland, Oreg., U.S.A. (as well as revisions thereof); PCI Express described in The PCI Express Base Specification of the PCI Special Interest Group, Revision 1.0a (as well as revisions thereof); PCI-x described in the PCI-X Specification Rev. 1.0a, Jul. 24, 2000, available from the aforesaid PCI Special Interest Group, Portland, Oreg., U.S.A. (as well as revisions thereof); and/or Universal Serial Bus (USB) (and related standards) as well as other interconnection standards.

Network component 118 may be capable of providing intercommunication between host system 102 and network 120 in compliance with any applicable protocols. Network component 118 may intercommunicate with host system 102 using bus 116. In one embodiment, network component 118 may be integrated into chipset 105. “Network component” may include any combination of digital and/or analog hardware and/or software on an I/O (input/output) subsystem that may process one or more network protocol units to be transmitted and/or received over a network. In one embodiment, the I/O subsystem may include, for example, a network component card (NIC), and network component may include, for example, a MAC (media access control) layer of the Data Link Layer as defined in the Open System Interconnection (OSI) model for networking protocols. The OSI model is defined by the International Organization for Standardization (ISO) located at 1 rue de Varembé, Case postale 56 CH-1211 Geneva 20, Switzerland.

Network 120 may be any network such as the Internet, an intranet, a local area network (LAN), storage area network (SAN), a wide area network (WAN), or wireless network. Network 120 may exchange traffic with network component 118 using the Ethernet standard (described in IEEE 802.3 and related standards) or any communications standard.

In some embodiments, host system may include logic capable of scheduling a prefetch of stored content from a destination buffer into a cache in connection with a request to determine an integrity validation value over stored content in a source buffer. In some embodiments, the stored content of the destination buffer may be a destination in which the stored content of the source buffer is to be written. In some embodiments, determination of an integrity validation value may include determination of a CRC value. In some embodiments, prefetching of content of the destination buffer may occur prior to completion of determining an integrity validation value over stored content in a source buffer.

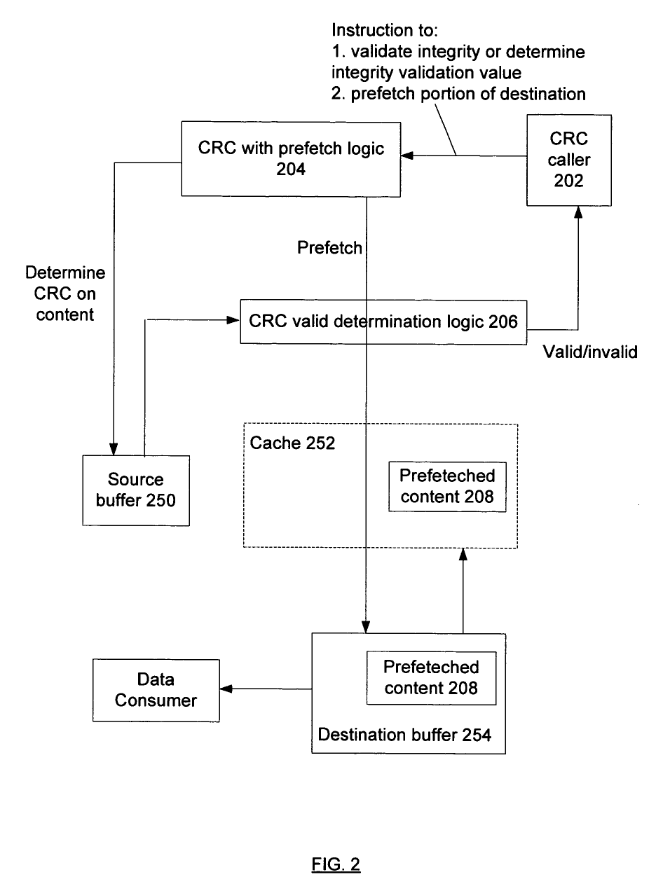

FIG. 2 depicts an example operation of some embodiments of the present invention in which prefetching of content from a destination buffer into a cache occurs prior to completion of determining an integrity validation value over content in a source buffer. For example, the example operation of FIG. 2 may occur in connection with RDMA protocol processing, iSCSI protocol processing, Infiniband protocol processing or any other protocol. For example, the source buffer may be a portion of a host memory. For example, the destination buffer may be a kernel buffer or application buffer. For example, if destination buffer includes either a kernel buffer or application, then a consumer (e.g., file system, application, kernel agent, kernel service) may use the data.

In some embodiments, CRC caller 202, CRC with prefetch logic 204, and CRC valid determination logic 206 may be implemented as machine executable instructions stored in a memory device, such as a host memory. However, CRC caller 202, CRC with prefetch logic 204, and CRC valid determination logic 206 may be implemented as any logic.

In this example, CRC caller 202 may issue a request to perform a determination of whether the integrity of content stored by source buffer 250 is valid or a request to determine an integrity validation value. In some embodiments, determining whether integrity is valid includes calculating a CRC value over a portion of content stored by source buffer 250 and comparing the calculation with a comparison CRC value. In some embodiments, CRC caller 202 may be an application executable by a processor or firmware. In some embodiments, CRC caller 202 may be part of a network stack such as but not limited to an RDMA, iSCSI, Infiniband, or other protocol processing layer. In this example, CRC caller 202 further issues a request to prefetch into a cache a portion of destination buffer 254 into which the portion of content of source buffer 250 may be subsequently written. In some embodiments, the prefetch request may be issued with the instruction to validate integrity of a portion of content stored by source buffer 250.

In some embodiments, CRC caller 202 may issue a request to determine an integrity validation value using content stored by source buffer 250. In some embodiments, the prefetch request may be issued with the instruction to determine the integrity validation value of a portion of content stored by source buffer 250.

In this example, CRC with prefetch logic 204 may receive the instruction to validate integrity (or instruction to determine an integrity validation value) with the prefetch request from CRC caller 202. For example, CRC with prefetch logic 204 may be an application, kernel code, operating system, driver, firmware, and/or other logic. CRC with prefetch logic 204 may issue a request to determine a CRC value over a portion of content stored by source buffer 250 specified in the instruction. CRC with prefetch logic 204 may be executable code stored in a memory and accessible when called by CRC caller 202. For example, in terms of use of clock cycles of a processor executing CRC with prefetch logic 204, determination of an integrity validation value may include spare cycles that can be used to determine when and what to prefetch from a destination buffer. Further, spare I/O bandwidth available during the CRC value determination may be available to support prefetch operations of content from destination buffer 254 into cache 252.

In response to the request to perform a determination of whether the integrity of content stored by source buffer 250 is valid or to determine a CRC value over a portion of content stored by source buffer 250, the portion of the content of source buffer 250 may be written into cache 252 (not shown). In some embodiments, the portion of source buffer 250 may be written into cache 252 in eight (8) byte increments, although other values may be used.

In some embodiments, determination of a CRC value over content in source buffer 250 may use table lookup and arithmetic-logic-unit operations in an instruction repeated in a loop. In some embodiments, determination of a CRC value may include calculations and/or uses of look-up-tables. In some embodiments, determination of a CRC value over content in source buffer 250 may use calculations. Any CRC determination techniques may be used.

During the determination of the CRC value, CRC with prefetch logic 204 may request transfer of a portion of destination buffer 254. For example, the portion of destination buffer 254 for which a transfer is requested may start at a starting destination address in which content from source buffer 250 being validated by CRC valid determination logic 206 is to be written. For example, in some embodiments, a prefetch of the portion of destination buffer 254 may be a cache lines worth, although other sizes may be used. In some embodiments, CRC with prefetch logic 204 may request a cache line worth of the destination buffer 254 after a CRC value has been determined over a cache line worth of content of the source buffer 250. The prefetched content is shown as prefetched content 208.

Following determination of the CRC value over the portion of source buffer 250, if requested, CRC valid determination logic 206 may determine whether the CRC value matches a CRC comparison value. CRC valid determination logic 206 may perform a comparison of the determined integrity validation value with a reference integrity validation value. For example, a reference integrity validation value may be a CRC value provided with a network protocol unit and transmitted from a transmitter. Any CRC validation techniques may be used.

Following determination of the CRC value over the portion of the source buffer 250, the CRC valid determination logic 206 may provide an indication whether the CRC value is valid or invalid to the CRC caller 202. In some embodiments, if the CRC is valid then the portion of source buffer 250 may be copied over the prefetched content 208 and subsequently written into the destination buffer 254 (not depicted). In some embodiments, the portion of source buffer 250 may include a portion of a network protocol unit. Subsequently, the portion of the source buffer 250 may be made available for further protocol processing or for access by an application program.

For example, in some embodiments, the determined CRC value and content in the source buffer over which a CRC value was determined may be transmitted in a network protocol unit to a receiver through a network.

In some embodiments, a TCP protocol compliance operation may occur prior to the CRC value determination or CRC value validation operations. For example, the TCP/IP protocol is described at least in the publication entitled “Transmission Control Protocol: DARPA Internet Program Protocol Specification,” prepared for the Defense Advanced Projects Research Agency (RFC 793, published September 1981). TCP protocol compliance may comprise, for example, verifying the sequence number of a received packet to ensure that the packet is within a range of numbers that was agreed upon between the communicating nodes; verifying the payload size to ensure that the packet is within a range of sizes that was agreed upon between the communicating nodes; ensuring that the header structure conforms to the protocol; and ensuring that the timestamps are within an expected time range.

Of course, in some embodiments, values other than a CRC value may be calculated or determined over a portion of content stored by source buffer 250, such as but not limited to a checksum.

Accordingly, in some embodiments, where data in a source buffer is to be validated and transferred to a destination buffer, prefetching content of the destination buffer to a cache prior to completion of a determination of an integrity validation value (e.g., CRC value) or validation of integrity of data in the source buffer may avoid delay in availability of data following CRC validation (or determination of a CRC value) of the data that could be caused by transferring content from the destination buffer to the cache following determination of an integrity validation value (e.g., CRC value) or validation of integrity of content in the source buffer.

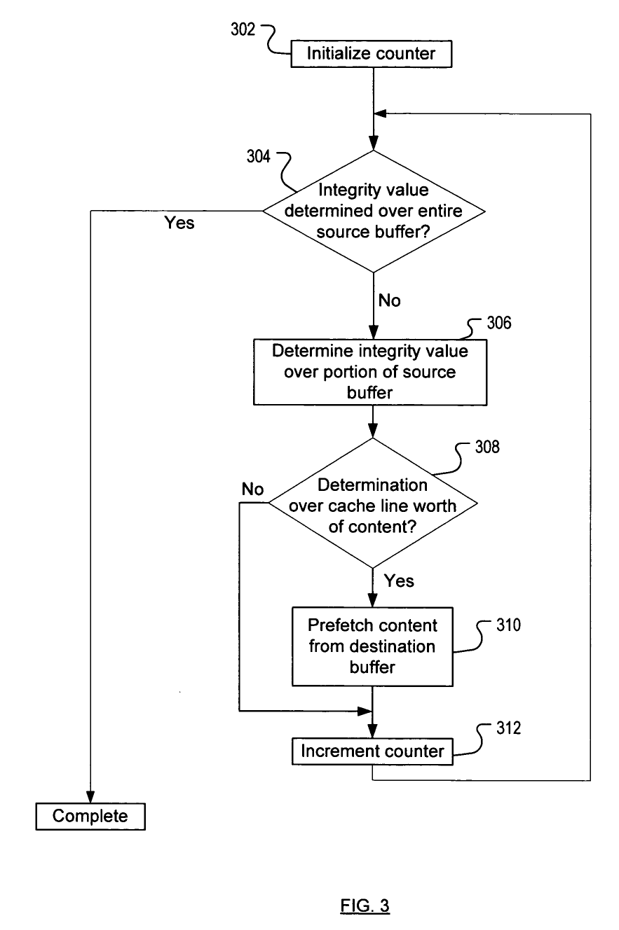

FIG. 3 depicts an example process 300 that can be used in embodiments of the present invention to determine when to prefetch portions of a destination buffer, in accordance with some embodiments of the present invention. For example, process 300 may occur prior to completion of an integrity validation value checking operation or prior to completion of determining an integrity validation value. For example, the integrity validation value may be a CRC value.

Process 300 may be executed in response to a request to determine an integrity validation value of the portion of stored content or validate integrity of a portion of stored content. Process 300 may provide for prefetching of at least some content from a destination buffer prior to completion of the request to determine an integrity validation value of a portion of stored content or prior to completion of the request to validate integrity of a portion of stored content. The retrieved content may be content that is to be overwritten by content involved in a determination of integrity validation value.

In block 302, process 300 may initialize a counter variable that tracks an amount of stored content in a source buffer over which an integrity validation value determination operation has been performed. For example, in block 302, the counter may be initialized to zero. For example, in some embodiments, the integrity validation value determination may include a CRC value determination, whereas in other embodiments, other values may be determined. In some embodiments, the source buffer may store portions of network protocol units received from a network. In some embodiments, the source buffer may store portions of network protocol units to be transmitted to a destination through a network.

In block 304, process 300 may determine whether an integrity validation value has been determined over the entire source buffer. For example, the source buffer may be a portion of stored content or entire stored content of a memory device that stores content of interest. For example, in block 304, process 300 may determine whether the value of the counter is less than a size of the source buffer. If an integrity validation value has been determined over the entire source buffer, then process 300 may end. If an integrity validation value has not been determined over the entire source buffer, then block 306 may follow.

In block 306, process 300 may determine an integrity validation value over a portion of the source buffer for which an integrity validation value was not previously determined. For example, in block 306, process 300 may track the portion of the source buffer for which an integrity validation value was not previously determined by use of the variable “counter”. For example, the portion of the source buffer for which an integrity validation is performed may be any size. The size may be fixed or increase or decrease as a function of time or amount of stored content over which an integrity validation value was determined. For example, the integrity validation value determination performed in block 306 may be in response to a received call to validate integrity or determine an integrity validation value. For example, a single request to determine an integrity validation value or a single request to validate integrity may include multiple performances of block 306.

In some embodiments, in block 306, for network protocol units to be transmitted through a network to a receiver, process 300 may perform a determination of an integrity validation value for the content to be transmitted in a network protocol unit. For example, in block 306, process 300 may perform a determination of a CRC value for the content. The CRC value may be transmitted as a CRC value with content in a network protocol unit to a destination.

In block 308, process 300 may determine whether an integrity validation value has been determined over an integer multiple of a cache line worth of the source buffer. For example, a cache line may be an amount of stored content a cache reads in at a time. Any size (in bytes) of cache line may be used. In some embodiments, a cache line is not used as a measure of content and a determination of whether an integrity computation has been performed over any size of content may be made. If an integrity validation has been performed over an integer multiple of a cache line worth of the source buffer, then block 310 may follow. If an integrity validation has not been performed over an integer multiple of a cache line worth of the source buffer, then block 312 may follow.

In block 310, process 300 may prefetch a portion of a destination buffer and store the portion into the cache. For example, the prefetched portion may be a cache line worth (or other amount or measure) of stored content from the destination buffer. For example, following each first execution of block 306, even though an integrity validation value has not been computed over an integer multiple of a cache line worth of content of the source buffer (or other amount or measure), process 300 may prefetch a cache line worth (or other amount or measure) of a portion of the destination buffer. For example, the starting position of stored content to be retrieved from the destination buffer may be determined using the variable “counter” so that previously prefetched content is not fetched again.

In block 312, process 300 may increment variable counter to account for the amount of stored content from a source buffer over which an integrity validation value determination operation was performed in block 306. In some embodiments, any amount of stored content may have an integrity validation value determination.

In some embodiments, following a determination of a validation value over the source buffer, the source buffer may be transferred to a destination buffer. In some embodiments, following validation of the source buffer by the computed value matching the reference validation value, the source buffer may be transferred to the destination buffer. For example, to transfer the content of the source buffer to the destination buffer, the content of the source buffer in the cache may overwrite the prefetched portion of the destination buffer in the cache and the overwritten portion of the destination buffer in the cache may be written into the destination buffer.

Following a determination of a validation value over the source buffer, a validation of the computed value may occur by comparing the computed value with a reference validation value. For example, the source buffer may include at least one packet received from a transmitter, the computed value may be a CRC value, and the reference validation value may be a CRC value transmitted with the at least one packet.

Following a determination of a validation value over the source buffer, the validation value may be transmitted with the content over which the validation value was determined in a network protocol unit to a receiver through a network.

Embodiments of the present invention may be implemented as any or a combination of: one or more microchips or integrated circuits interconnected using a motherboard, hardwired logic, machine readable instructions stored by a memory device and executed by a microprocessor, firmware, an application specific integrated circuit (ASIC), and/or a field programmable gate array (FPGA). The term “logic” may include, by way of example, software or hardware and/or combinations of software and hardware.

Embodiments of the present invention may be provided, for example, as a computer program product which may include one or more machine-readable media having stored thereon machine-executable instructions that, when executed by one or more machines such as a computer, network of computers, or other electronic devices, may result in the one or more machines carrying out operations in accordance with embodiments of the present invention. A machine-readable medium may include, but is not limited to, floppy diskettes, optical disks, CD-ROMs (Compact Disc-Read Only Memories), and magneto-optical disks, ROMs (Read Only Memories), RAMs (Random Access Memories), EPROMs (Erasable Programmable Read Only Memories), EEPROMs (Electrically Erasable Programmable Read Only Memories), magnetic or optical cards, flash memory, or other type of media/machine-readable medium suitable for storing machine-executable instructions.

Moreover, embodiments of the present invention may also be downloaded as a computer program product, wherein the program may be transferred from a remote computer (e.g., a server) to a requesting computer (e.g., a client) by way of one or more data signals embodied in and/or modulated by a carrier wave or other propagation medium via a communication link (e.g., a modem and/or network connection). Accordingly, as used herein, a machine-readable medium may, but is not required to, comprise such a carrier wave.

The drawings and the forgoing description gave examples of the present invention. Although depicted as a number of disparate functional items, those skilled in the art will appreciate that one or more of such elements may well be combined into single functional elements. Alternatively, certain elements may be split into multiple functional elements. Elements from one embodiment may be added to another embodiment. For example, orders of processes described herein may be changed and are not limited to the manner described herein. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A method comprising:
determining an integrity validation value over a portion of contents of a first buffer; and
prior to completion of the determining the integrity validation value, requesting transfer of a portion of a second buffer to a cache.

2. The method of claim 1, wherein the determining the integrity validation value includes determining a CRC value.

3. The method of claim 1, further comprising comparing the determined integrity validation value with a reference value.

4. The method of claim 1, wherein the contents of the first buffer comprise a portion of a network protocol unit received from a transmitter and wherein the reference value is provided with the network protocol unit.

5. The method of claim 1, further comprising:
in the cache, overwriting the requested portion of the second buffer with contents from the first buffer; and
transferring the overwritten portion from the cache to the second buffer.

6. The method of claim 1, wherein the requesting transfer comprises:
selectively requesting transfer of a quantity of content from the second buffer to the cache in response to determining an integrity validation value over a multiple of the quantity of contents of the first buffer.

7. The method of claim 1, wherein the requesting transfer further comprises:
selectively requesting transfer from the second buffer to the cache of a quantity of content in response to commencing determining an integrity validation value over contents of the first buffer.

8. The method of claim 1, wherein the contents of the first buffer comprise contents to be transmitted in a network protocol unit to a receiver and wherein the determined integrity validation value is to be included in the network protocol unit to be transmitted.

9. The method of claim 1, wherein the requesting transfer comprises requesting transfer during free cycles of an input/output logic.

10. An apparatus comprising:
logic to determine an integrity validation value over a portion of contents of a first buffer; and
logic to request transfer of a portion of a second buffer to a cache prior to completion of the determination of the integrity validation value.

11. The apparatus of claim 10, wherein the logic to determine the integrity validation value is to determine a CRC value.

12. The apparatus of claim 10, further comprising logic to compare the determined integrity validation value with a reference value.

13. The apparatus of claim 10, wherein the contents of the first buffer comprise a portion of a network protocol unit received from a transmitter and wherein the reference value is provided with the network protocol unit.

14. The apparatus of claim 10, further comprising:
logic to overwrite in the cache the requested portion of the second buffer with contents from the first buffer; and
logic to transfer the overwritten portion from the cache to the second buffer.

15. The apparatus of claim 10, wherein the logic to request transfer comprises:
logic to selectively request transfer of a quantity of content from the second buffer to the cache in response to determination of an integrity validation value over a multiple of the quantity of contents of the first buffer.

16. The apparatus of claim 10, wherein the logic to request transfer comprises:
logic to selectively request transfer from the second buffer to the cache of a quantity of content in response to commencement of the determination of an integrity validation value over contents of the first buffer.

17. The apparatus of claim 10, wherein the contents of the first buffer comprise contents to be transmitted in a network protocol unit to a receiver and wherein the determined integrity validation value is to be included in the network protocol unit to be transmitted.

18. The apparatus of claim 10, wherein the logic to request transfer comprises logic to request transfer during free cycles of an input/output logic.

19. A system comprising:
a host computer comprising:
logic to determine an integrity validation value over a portion of contents of a first buffer, and
logic to request transfer of a portion of a second buffer to a cache prior to completion of the determination of the integrity validation value;
a network component communicatively coupled to the host computer; and
a storage device communicatively coupled to the host computer.

20. The system of claim 19, wherein the logic to determine the integrity validation value is to determine a CRC value.

21. The system of claim 19, further comprising logic to compare the determined integrity validation value with a reference value.
